(19) United States
(12) Patent Application Publication
(10) Pub. No.: US 2026/0282611 A1
(43) Pub. Date: Sep. 17, 2026

(54) DISPLAY DEVICE AND METHOD OF MANUFACTURING DISPLAY DEVICE

(71) Applicant: SAMSUNG ELECTRONICS CO., LTD., Suwon-si (KR)

(72) Inventors: Junhee CHOI, Suwon-si (KR); Nakhyun Kim, Suwon-si (KR); Joohun Han, Suwon-si (KR)

(73) Assignee: SAMSUNG ELECTRONICS CO., LTD., Suwon-si (KR)

(21) Appl. No.: 19/349,461

(22) Filed: Oct. 3, 2025

(30) Foreign Application Priority Data
Mar. 11, 2025 (KR) 10-2025-0031662

(51) Int. Cl. H10H 20/825; H10H 20/01; H10H 20/821; H10H 20/824

(52) U.S. Cl. CPC H10H 20/8252; H10H 20/0137; H10H 20/821; H10H 20/8242

(57) ABSTRACT

Provided is a display device including a first light-emitting structure including a first light-emitting element, a second light-emitting structure including a second light-emitting element, and a third light-emitting structure including a third light-emitting element, wherein the first light-emitting element, the second light-emitting element, and the third light-emitting element respectively includes a first semiconductor layer of a first conductivity type, an active layer, and a second semiconductor layer of a second conductivity type that are sequentially stacked, and at least one of the second semiconductor layer in the first light-emitting element, the second semiconductor layer in the second light-emitting element, and the second semiconductor layer in the third light-emitting element includes a magnesium (Mg) dopant or zinc (Zn) dopant.

### CROSS-REFERENCE TO RELATED APPLICATION

This application claims priority to Korean Patent Application No. 10-2025-0031662 filed on Mar. 11, 2025, in the Korean Intellectual Property Office, the disclosure of which is incorporated by reference herein in its entirety.

### BACKGROUND

### 1. Field

Embodiments of the present disclosure relate to a display device and a method of manufacturing a display device.

### 2. Description of Related Art

In a monolithic light source, light sources may be positioned horizontally or vertically. A horizontal arrangement method is a method of placing red-green-blue (RGB) light sources horizontally, and may implement a structure enabling an increase in the light extraction efficiency of each RGB light source, but there is a limit in resolution.

On the other hand, a vertical stacking method is a method implemented by stacking RGB light sources vertically, which has the advantages of no loss of resolution and low driving current density, but the RGB light sources may be damaged during an etching process after stacking the RGB light sources, which may decrease the light extraction efficiency and brightness thereof.

### SUMMARY

Provided is a display device with improved light extraction efficiency and brightness, and a method of manufacturing the display device may be provided.

Additional aspects will be set forth in part in the description which follows and, in part, will be apparent from the description, or may be learned by practice of the presented embodiments of the disclosure.

According to an aspect of the disclosure, there is provided a display device including a first light-emitting structure including a first light-emitting element, a second light-emitting structure including a second light-emitting element, and a third light-emitting structure including a third light-emitting element, wherein the first light-emitting element, the second light-emitting element, and the third light-emitting element respectively includes a first semiconductor layer of a first conductivity type, an active layer, and a second semiconductor layer of a second conductivity type that are sequentially stacked, and at least one of the second semiconductor layer in the first light-emitting element, the second semiconductor layer in the second light-emitting element, and the second semiconductor layer in the third light-emitting element includes a magnesium (Mg) dopant or zinc (Zn) dopant.

The first semiconductor layer, the active layer, and the second semiconductor layer in each of the first light-emitting element, the second light-emitting element, and the third light-emitting element may include gallium nitride (GaN) or indium gallium nitride (InGaN), and at least one of the second semiconductor layer in the first light-emitting element, the second semiconductor layer in the second light-emitting element, and the second semiconductor layer in the third light-emitting element may include a Mg dopant.

The first semiconductor layer, the active layer, and the second semiconductor layer in each of the first light-emitting element, the second light-emitting element, and the third light-emitting element may include aluminum gallium indium phosphide (AlGaInP), and at least one of the second semiconductor layer in the first light-emitting element, the second semiconductor layer in the second light-emitting element, and the second semiconductor layer in the third light-emitting element may include a Zn dopant.

A doping concentration of Mg or a doping concentration of Zn on a first surface of at least one of the second semiconductor layer in the first light-emitting element, the second semiconductor layer in the second light-emitting element, and the second semiconductor layer in the third light-emitting element may be greater than a doping concentration of Mg or a doping concentration of Zn on a second surface of surface thereof opposite to the first surface.

A doping concentration of Mg or a doping concentration of Zn of at least one of the second semiconductor layer in the first light-emitting element, the second semiconductor layer in the second light-emitting element, and the second semiconductor layer in the third light-emitting element may decrease from a first surface of at least one of the second semiconductor layer in the first light-emitting element, the second semiconductor layer in the second light-emitting element, and the second semiconductor layer in the third light-emitting element to a second surface thereof opposite to the first surface.

In at least one of the second semiconductor layer in the first light-emitting element, the second semiconductor layer in the second light-emitting element, and the second semiconductor layer in the third light-emitting element, a doping concentration of Mg or Zn on a first surface of the second semiconductor layer may be greater than or equal to 5×10²⁰cm⁻³ and less than or equal to 2×10²¹cm⁻³.

In at least one of the second semiconductor layer in the first light-emitting element, the second semiconductor layer in the second light-emitting element, and the second semiconductor layer in the third light-emitting element, a doping concentration of Mg or Zn on a first surface of the second semiconductor layer may be greater than or equal to 7×10²⁰cm⁻³ and less than or equal to 2×10²¹cm⁻³.

In at least one of the second semiconductor layer in the first light-emitting element, the second semiconductor layer in the second light-emitting element, and the second semiconductor layer in the third light-emitting element, a doping concentration of Mg or Zn on a first surface of the second semiconductor layer may be greater than or equal to 8×10²⁰cm⁻³ and less than or equal to 2×10²¹cm⁻³.

At least one of the first light-emitting element, the second light-emitting element, and the third light-emitting element may include a diffusion barrier layer.

At least one of the first light-emitting element, the second light-emitting element, and the third light-emitting element may include a diffusion barrier layer, and the diffusion barrier layer may include at least one of aluminum nitride (AlN), titanium nitride (TiN), silicon nitride (SiN), aluminum oxide (Al₂O₃) or a combination thereof.

The second light-emitting structure may include the first light-emitting element and the second light-emitting element stacked on the first light-emitting element, and the third light-emitting structure may include the first light-emitting element, the second light-emitting element stacked on the first light-emitting element, and the third light-emitting element stacked on the second light-emitting element.

The second light-emitting structure may include the first light-emitting element and the second light-emitting element stacked on the first light-emitting element, the third light-emitting structure may include the first light-emitting element, the second light-emitting element stacked on the first light-emitting element, and the third light-emitting element stacked on the second light-emitting element, and the second semiconductor layer in the first light-emitting element may include a Mg dopant or a Zn dopant, and the second semiconductor layer in the second light-emitting element may include a Mg dopant or a Zn dopant.

The first light-emitting structure, the second light-emitting structure, and the third light-emitting structure may be sequentially stacked in a vertical direction.

The first light-emitting structure, the second light-emitting structure, and the third light-emitting structure may be adjacent to each other in a horizontal direction.

The first light-emitting structure, the second light-emitting structure, and the third light-emitting structure may be adjacent to each other in a horizontal direction, and a portion of at least one of the second semiconductor layer in the first light-emitting structure, the second semiconductor layer in the second light-emitting structure, and the second semiconductor layer in the third light-emitting structure may include a Mg dopant or a Zn dopant.

According to an aspect of the disclosure, there is provided a method of manufacturing a display device, the method including forming a first light-emitting element, a second light-emitting element, and a third light-emitting element respectively including a first semiconductor layer of a first conductivity type, an active layer, and a second semiconductor layer of a second conductivity type that are sequentially stacked, depositing a magnesium (Mg) film or a zinc (Zn) film on at least one of the second semiconductor layer in the first light-emitting element, the second semiconductor layer in the second light-emitting element, and the second semiconductor layer in the third light-emitting element, diffusing a Mg dopant or a Zn dopant by heat treating at least one of the first light-emitting element, the second light-emitting element, and the third light-emitting element, and removing residual Mg or Zn from at least one of the first light-emitting element, the second light-emitting element, and the third light-emitting element.

The first semiconductor layer, the active layer, and the second semiconductor layer in each of the first light-emitting element, the second light-emitting element, and the third light-emitting element may include gallium nitride (GaN) or indium gallium nitride (InGaN), and at least one of the second semiconductor layer in the first light-emitting element, the second semiconductor layer in the second light-emitting element, and the second semiconductor layer in the third light-emitting element may include a Mg dopant.

The first semiconductor layer, the active layer, and the second semiconductor layer in the first light-emitting element, the second light-emitting element, and the third light-emitting element, respectively may include aluminum gallium indium phosphide (AlGaInP), and at least one of the second semiconductor layer in the first light-emitting element, the second semiconductor layer in the second light-emitting element, and the second semiconductor layer in the third light-emitting element may include a Zn dopant.

A doping concentration of Mg or a doping concentration of Zn on a first surface of at least one of the second semiconductor layer in the first light-emitting element, the second semiconductor layer in the second light-emitting element, and the second semiconductor layer in the third light-emitting element may be greater than a doping concentration of Mg or a doping concentration of Zn on a second surface opposite to the first surface.

The method may further include, prior to the depositing of the Mg film or the Zn film on at least one of the second semiconductor layer in the first light-emitting element, the second semiconductor layer in the second light-emitting element, and the second semiconductor layer in the third light-emitting element, forming a diffusion barrier layer on at least one of the first light-emitting element, the second light-emitting element, and the third light-emitting element.

### BRIEF DESCRIPTION OF DRAWINGS

The above and other aspects, features, and advantages of embodiments of the disclosure will be more apparent from the following description taken in conjunction with the accompanying drawings, in which:

FIG. 1 is a cross-sectional view illustrating a display device according to one or more embodiments;

FIGS. 2, 3, 4, and 5 are diagrams illustrating a method of manufacturing the display device of FIG. 1;

FIG. 6 is a flowchart illustrating a method of manufacturing the display device of FIG. 1;

FIG. 7 is a cross-sectional view illustrating a display device according to one or more other embodiments;

FIG. 8 is a cross-sectional view illustrating a display device according to one or more other embodiments;

FIG. 9 is a block diagram of an electronic device including a display device according to one or more embodiments;

FIG. 10 illustrates an example of an electronic device applied to a mobile device, according to one or more embodiments;

FIG. 11 illustrates an example of a display device applied to a car, according to one or more embodiments;

FIG. 12 illustrates an example of a display device applied to augmented reality glasses or virtual reality glasses, according to one or more embodiments; FIG. 13 illustrates an example of a display device applied to a large signage, according to one or more embodiments; and

FIG. 14 illustrates an example of a display device applied to a wearable display, according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, with reference to the attached drawings, a display device and a method of manufacturing the display device are described in detail. In the attached drawings, the same reference numerals refer to the same components, and the size of each component in the drawings may be exaggerated for clarity and convenience of description. In addition, various embodiments described below are merely examples, and various modifications may be made for the embodiments.

Hereinafter, the terms “upper” or “on” may include not only being located above while being in direct contact, but also being located above without being in contact. Singular expressions include plural expressions unless the context clearly indicates otherwise. Additionally, when a part is described to “include” a component, this does not mean that the part excludes other components, but rather means that the part may further include other components, unless otherwise specifically described.

The use of the article “the” and similar referential terms to indicate a referent may refer to both singular and plural referents. Unless operations of a method are explicitly described in a specific order or to the contrary, these operations may be performed in any suitable order and are not necessarily limited to the order described.

Connections of lines between components depicted in the drawings or connection members are merely illustrative of functional connections and/or physical or circuit connections, and in an actual device, may be represented as alternative or additional various functional connections, physical connections, or circuit connections.

Any use of examples or terms thereof is merely intended to elaborate technical ideas and is not intended to limit the scope of the disclosure unless otherwise defined by the claims.

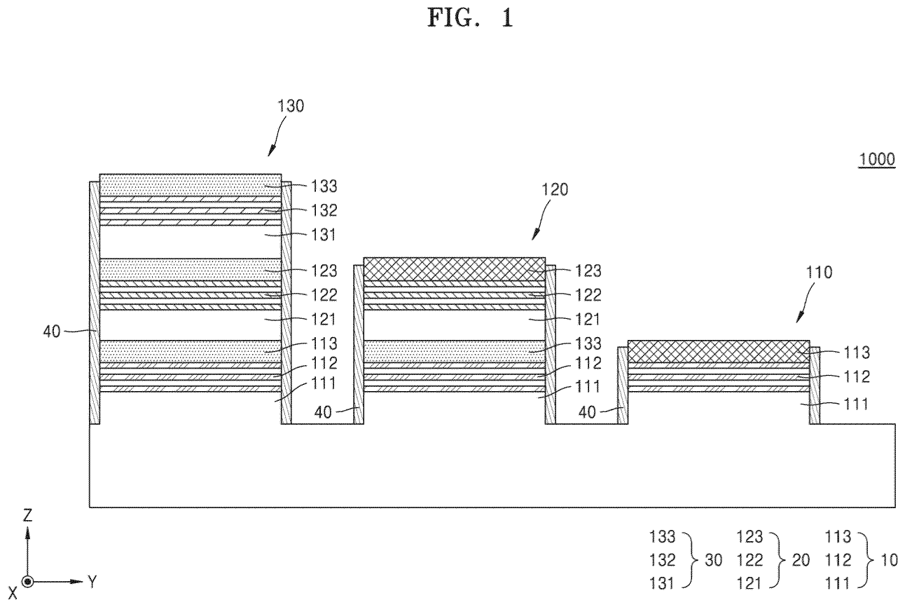

FIG. 1 is a cross-sectional view illustrating a display device according to one or more embodiments.

Referring to FIG. 1, a display device 1000 may include at least one light-emitting structure 110, 120, and 130. Each of the light-emitting structures 110, 120, and 130 may include at least one light-emitting element 10, 20, and 30 that is sequentially monolithically stacked. For example, a first light-emitting structure 110 may include a first light-emitting element 10, a second light-emitting structure 120 may include a structure in which the first light-emitting element 10 and a second light-emitting element 20 are sequentially stacked, and a third light-emitting structure 130 may include a structure in which the first light-emitting element 10, the second light-emitting element 20, and a third light-emitting element 30 are sequentially stacked.

The first light-emitting element 10 may include a structure in which a first semiconductor layer 111 of a first conductivity type, an active layer 112, and a second semiconductor layer 113 of a second conductivity type different from the first conductivity type are sequentially stacked. Each of the first semiconductor layer 111, the active layer 112, and the second semiconductor layer 113 of the first light-emitting element 10 may be provided along a first direction (an X direction) and a second direction (a Y direction), and the first semiconductor layer 111, the active layer 112, and the second semiconductor layer 113 may be sequentially stacked along a third direction (a Z direction). The first light-emitting element 10 may include, for example, a structure for emitting blue light. However, embodiments are not limited thereto.

The second light-emitting element 20 may include a structure in which a first semiconductor layer 121 of a first conductivity type, an active layer 122, and a second semiconductor layer 123 of a second conductivity type different from the first conductivity type are sequentially stacked. Each of the first semiconductor layer 121, the active layer 122, and the second semiconductor layer 123 of the second light-emitting element 20 may be provided along the first direction (the X direction) and the second direction (the Y direction), and the first semiconductor layer 121, the active layer 122, and the second semiconductor layer 123 may be sequentially stacked along the third direction (the Z direction). The second light-emitting element 20 may include, for example, a structure for emitting green light. However, embodiments are not limited thereto.

The third light-emitting element 30 may include a structure in which a first semiconductor layer 131 of a first conductivity type, an active layer 132, and a second semiconductor layer 133 of a second conductivity type different from the first conductivity type are sequentially stacked. Each of the first semiconductor layer 131, the active layer 132, and the second semiconductor layer 133 of the third light-emitting element 30 may be provided along the first direction (the X direction) and the second direction (the Y direction), and the first semiconductor layer 131, the active layer 132, and the second semiconductor layer 133 may be sequentially stacked along the third direction (the Z direction). The third light-emitting element 30 may include, for example, a structure for emitting red light. However, embodiments are not limited thereto.

The first semiconductor layers 111, 121, and 131 may be doped with dopant of a first conductivity type, and the second semiconductor layers 113, 123, and 133 may be doped with dopant of a second conductivity type that is electrically opposite to the first conductivity type. For example, the first semiconductor layers 111, 121, and 131 may be doped with n-type dopant and the second semiconductor layers 113, 123, and 133 may be doped with p-type dopant, or the first semiconductor layers 111, 121, and 131 may be doped with p-type dopant and the second semiconductor layers 113, 123, and 133 may be doped with n-type dopant. One of the first semiconductor layers 111, 121, and 131 and the second semiconductor layers 113, 123, and 133 may include a group III-V compound semiconductor layer of n-type, and the other may include a group III-V compound semiconductor layer of p-type.

The active layers 112, 122, and 132 may generate light by recombination of electrons and holes provided from the first semiconductor layers 111, 121, and 131 and the second semiconductor layers 113, 123, and 133. For example, the active layers 112, 122, and 132 may have a quantum well structure with quantum wells placed between barriers. The wavelength of light emitted from the active layers 112, 122, and 132 may be determined by an energy band gap of material constituting the quantum wells in the active layers 112, 122, and 132. The active layers 112, 122, and 132 may include only a single quantum well, or may include a multi-quantum well (MQW) structure with multiple quantum wells arranged therein. The energy of quantum well in a conduction band may be chosen to be lower than the energy of barrier thereof. For example, barriers and quantum wells within the active layers 112, 122, and 132 may include different compound semiconductors from each other, or compound semiconductors having different compositions from each other.

The first semiconductor layers 111, 121, and 131, the active layers 112, 122, and 132, and the second semiconductor layers 113, 123, and 133 may include a group III-V compound semiconductor based on, for example, gallium nitride (GaN). For example, the first semiconductor layers 111, 121, and 131, the active layers 112, 122, 132, and the second semiconductor layers 113, 123, and 133 may include a group III-V compound semiconductor such as GaN, indium gallium nitride (InGaN), aluminum indium gallium nitride (AlInGaN), aluminum gallium indium phosphide (AlGaInP), etc., and the first semiconductor layers 111, 121, and 131 and the second semiconductor layers 113, 123, and 133 may be doped with dopant of opposite types to each other.

For example, the first semiconductor layers 111, 121, and 131 and the second semiconductor layers 113, 123, and 133 may include GaN and be oppositely doped to each other. For example, the first semiconductor layers 111, 121, and 131 may include n-type doped GaN layers, and the second semiconductor layers 113, 123, and 133 may include p-type doped GaN layers. As another example, the first semiconductor layers 111, 121, and 131 may include p-type doped GaN layers, and the second semiconductor layers 113, 123, and 133 may include n-type doped GaN layers. The active layers 112, 122, and 132 may include, for example, InGaN, and may have different composition ratios of indium (In) and gallium (Ga) depending on the emission wavelength to be desired.

In each of the first light-emitting element 10, the second light-emitting element 20, and the third light-emitting element 30, the active layers 112, 122, and 132 may include a stacked structure of a first barrier/a quantum well/a second barrier, for example. The first barrier can include, for example, a GaN barrier, which may or may not be doped with silicon (Si). The quantum well may have a single quantum well structure or a multiple quantum well structure. For example, the quantum well may include a single-stacked structure of InGaN/GaN or InGaN/GaN/AlGaN, or a multi-stacked structure thereof. A composition ratio of In and Ga in InxGa1-xN stacked structure forming the quantum well may vary depending on the emission wavelength. The GaN in the stacked structure forming the quantum well may be Si-doped or undoped.

For example, when blue light, green light, and red light are respectively generated from the first light-emitting element 10, the second light-emitting element 20, and the third light-emitting element 30, the active layer 122 of the second light-emitting element 20 and the active layer 132 of the third light-emitting element 30 may or may not include AlGaN, and the active layer 112 of the first light-emitting element 10 may not include AlGaN. For example, in the active layer 122 of the second light-emitting element 20 and the active layer 132 of the third light-emitting element 30, the quantum well may include a single-stacked structure of InxGa1-xN/GaN or InxGa1-xN/GaN/AlGaN, or a multi-stacked structure thereof, and in the active layer 112 of the first light-emitting element 10, the quantum well may include a single-stacked structure of InxGa1-xN/GaN, or a multi-stacked structure thereof.

In an etching process of the light-emitting elements 10, 20, and 30 which are monolithically stacked, damage may occur to the second semiconductor layer 113 of the first light-emitting element 10 of the first light-emitting structure 110 and the second semiconductor layer 123 of the second light-emitting element 20 of the second light-emitting structure 120, or a deactivation phenomenon of dopants may occur due to selective growth of a semiconductor layer.

In order to recover the second semiconductor layer 113 of the first light-emitting element 10 of the first light-emitting structure 110 and the second semiconductor layer 123 of the second light-emitting element 20 of the second light-emitting structure 120, magnesium (Mg) or zinc (Zn) dopants may be injected into the second semiconductor layer 113 of the first light-emitting element 10 of the first light-emitting structure 110 and the second semiconductor layer 123 of the second light-emitting element 20 of the second light-emitting structure 120.

According to one or more embodiments, at least one of the second semiconductor layer 113 of the first light-emitting element 10 of the first light-emitting structure 110, the second semiconductor layer 123 of the second light-emitting element 20 of the second light-emitting structure 120 and the second semiconductor layer 133 of the third light-emitting element 30 of the third light-emitting structure 130 may include Mg or Zn dopants.

According to one or more embodiments, the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130 may all include Mg or Zn dopants. As another example, the second semiconductor layer 133 of the third light-emitting element 30 of the third light-emitting structure 130 may not include Mg or Zn dopants, and the second semiconductor layer 113 of the first light-emitting element 10 of the first light-emitting structure 110 and the second semiconductor layer 123 of the second light-emitting element 20 of the second light-emitting structure 120 may include Mg or Zn dopants.

According to one or more embodiments, when the first semiconductor layers 111, 121, and 131, the active layers 112, 122, and 132, and the second semiconductor layers 113, 123, and 133 include GaN or InGaN, at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130 may include Mg dopants.

According to one or more embodiments, when the first semiconductor layers 111, 121, and 131, the active layers 112, 122, and 132, and the second semiconductor layers 113, 123, and 133 include AlGaInP, at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130 may include the Zn dopants.

According to one or more embodiments, the light-emitting elements 10, 20, and 30 respectively including the second semiconductor layers 113, 123, and 133 having a diffusion profile of Mg or Zn, which are respectively located at upper portions in the light-emitting structures 110, 120, and 130, may generate light. The diffusion profile of Mg or Zn may refer to a profile in which a doping concentration of Mg or Zn is highest on a first surface (e.g., an upper surface thereof) of the second semiconductor layers 113, 123, and 133, and a doping concentration of Mg or Zn decreases toward a second surface of the second semiconductor layers 113, 123, and 133 (e.g., a lower surface thereof) opposite to the first surface of the second semiconductor layers 113, 123, and 133. For example, in the first light-emitting structure 110, the first light-emitting element 10 including the second semiconductor layer 113 containing Mg or Zn dopants may generate blue light, in the second light-emitting structure 120, the second light-emitting element 20 including the second semiconductor layer 123 containing Mg or Zn dopants may generate green light, and in the third light-emitting structure 130, the third light-emitting element 10 including the second semiconductor layer 133 containing Mg or Zn dopants may generate red light.

According to one or more embodiments, in at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130, a doping concentration of Mg or Zn on one surface of the second semiconductor layers 113, 123, and 133 may be greater than a doping concentration of Mg or Zn on the other surface of the second semiconductor layers 113, 123, and 133.

According to one or more embodiments, in at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130, a doping concentration of Mg or Zn on one surface of the second semiconductor layers 113, 123, and 133 may be greater than or equal to about 5×10²⁰cm⁻³ but less than or equal to about 2×10²¹cm⁻³. As another example, in at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130, a doping concentration of Mg or Zn on one surface of the second semiconductor layers 113, 123, and 133 may be about 7×10²⁰cm⁻³ or more but about 2×10²¹cm⁻³ or less. As another example, in at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130, a doping concentration of Mg or Zn on one surface of the second semiconductor layers 113, 123, and 133 may be greater than or equal to about 8×10²⁰cm⁻³ but less than or equal to about 2×10²¹cm⁻³.

According to one or more embodiments, in at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130, a doping concentration of Mg or Zn of the second semiconductor layers 113, 123, and 133 may be highest on a first surface of the second semiconductor layers 113, 123, and 133, and may decrease toward a second surface of the second semiconductor layers 113, 123, and 133 opposite to the surface of the second semiconductor layers 113, 123, and 133.

According to one or more embodiments, a thickness of a portion doped with Mg or Zn in at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130 may be greater than or equal to about 5 nm but less than or equal to about 50 nm. As another example, the thickness of a portion doped with Mg or Zn in at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130 may be about 5 nm or more and about 30 nm or less.

According to one or more embodiments, the diffusion profile of Mg or Zn dopants may be formed in at least one of the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130. Accordingly, by enhancing hole injection into the second semiconductor layers 113, 123, and 133, the light extraction efficiency and brightness of the display device 1000 may increase.

Additionally, at least one of the light-emitting structures 110, 120, and 130 may further include a diffusion barrier layer 40 that is provided to extend in the third direction (the Z direction). The diffusion barrier layer 40 may include, for example, at least one of aluminum nitride (AlN), titanium nitride (TiN), silicon nitride (SiN), aluminum oxide (Al₂O₃) or a combination thereof. The diffusion barrier layer 40 may prevent lateral diffusion of Mg or Zn. However, embodiments are not limited thereto, and, for example, the diffusion barrier layer 40 may be omitted in at least one of the light-emitting structures 110, 120, and 130.

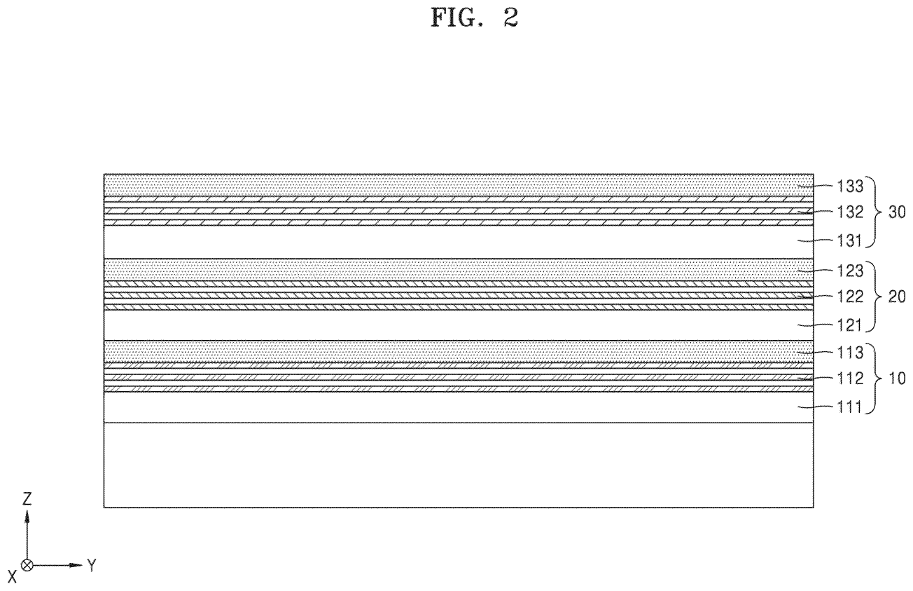

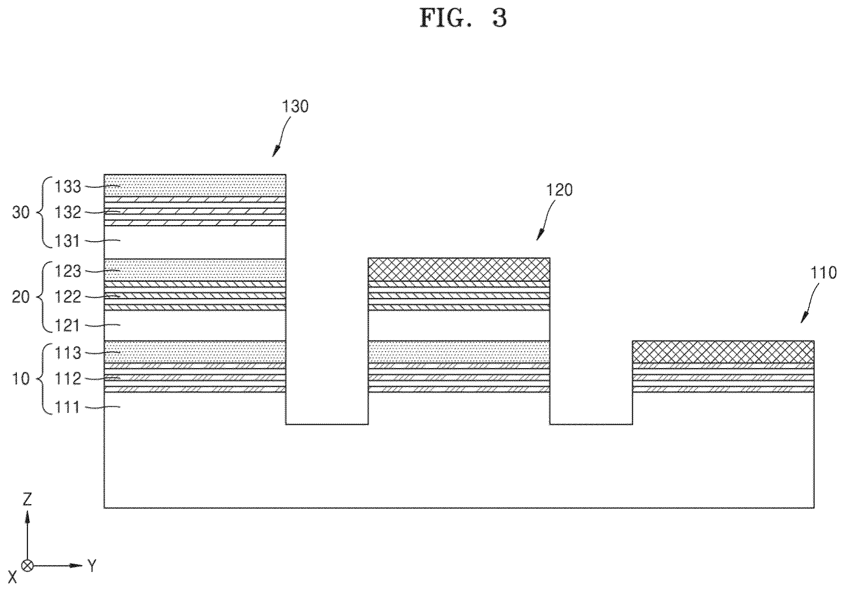

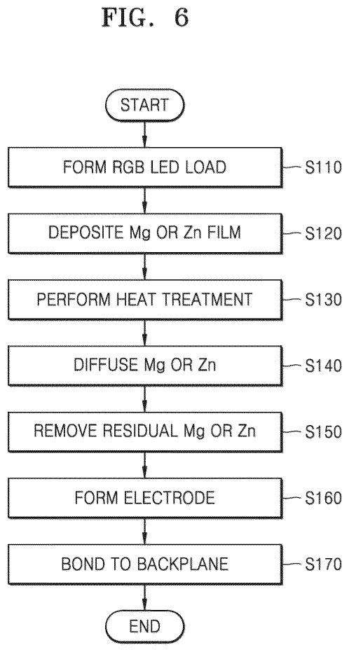

FIGS. 2 to 5 are diagrams illustrating a method of manufacturing the display device 1000 of FIG. 1, and FIG. 6 is a flowchart illustrating the method of manufacturing the display device 1000 of FIG. 1. The following description is provided together with reference to FIG. 6.

Referring to FIG. 2, the first light-emitting element 10, the second light-emitting element 20, and the third light-emitting element 30 may be sequentially formed in the third direction (the Z direction). For example, the first semiconductor layer 111, the active layer 112, and the second semiconductor layer 113 of the first light-emitting element 10 may be sequentially grown, the first semiconductor layer 121, the active layer 122, and the second semiconductor layer 123 of the second light-emitting element 20 may then be sequentially grown, and the first semiconductor layer 131, the active layer 132, and the second semiconductor layer 133 of the third light-emitting element 30 may then be sequentially grown.

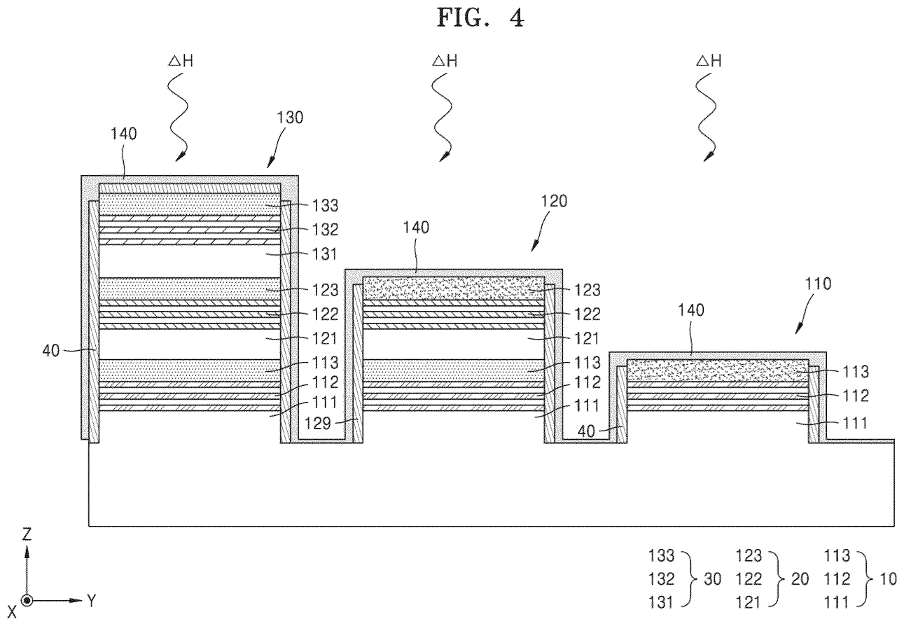

Referring to FIG. 3, the first light-emitting element 10, the second light-emitting element 20, and the third light-emitting element 30, which are sequentially stacked, may be etched by, for example, a plasma etching process so that the second semiconductor layer 113 of the first light-emitting element 10 and the second semiconductor layer 123 of the second light-emitting element 20 are exposed, thereby forming the first light-emitting structure 110, the second light-emitting structure 120, and the third light-emitting structure 130, and a red green blue (RGB) light-emitting diode (LED) load (S110). At this time, the second semiconductor layer 113 of the first light-emitting element 10 of the first light-emitting structure 110 and the second semiconductor layer 123 of the second light-emitting element 20 of the second light-emitting structure 120 may be damaged by plasma.

Referring to FIG. 4, in order to repair the second semiconductor layer 113 of the first light-emitting element 10 of the first light-emitting structure 110 and the second semiconductor layer 123 of the second light-emitting element 20 of the second light-emitting structure 120 damaged by plasma, a Mg or Zn film 140 may be deposited on the first light-emitting structure 110, the second light-emitting structure 120, and the third light-emitting structure 130 (S120).

Thereafter, heat treatment may be performed on the first light-emitting structure 110, the second light-emitting structure 120, and the third light-emitting structure 130 (S130), and Mg or Zn dopants may be diffused into the second semiconductor layer 113 of the first light-emitting element 10 of the first light-emitting structure 110, the second semiconductor layer 123 of the second light-emitting element 20 of the second light-emitting structure 120, and the second semiconductor layer 133 of the third light-emitting element 30 of the third light-emitting structure 130 (S140). The heat treatment may be performed, for example, at about 500° C. to about 900° C. After performing the heat treatment, unreacted residual Mg or Zn dopants may be removed through, for example, a wet cleaning process (S150).

According to one or more embodiments, before depositing the Mg or Zn film 140 on the first light-emitting structure 110, the second light-emitting structure 120, and the third light-emitting structure 130, the diffusion barrier layer 40 may be deposited on the first light-emitting structure 110, the second light-emitting structure 120, and the third light-emitting structure 130. The diffusion barrier layer 40 may be provided to extend in the third direction (the Z direction) along walls (sidewalls) of each of the first light-emitting structure 110, the second light-emitting structure 120, and the third light-emitting structure 130.

According to one or more embodiments, the Mg or Zn film 140 may be deposited on the first light-emitting structure 110 and the second light-emitting structure 120, and the Mg or Zn film 140 may not be deposited on the third light-emitting structure 130. Additionally, according to one or more embodiments, the diffusion barrier layer 40 may also be provided on the second semiconductor layer 133 of the third light-emitting element 30 of the third light-emitting structure 130.

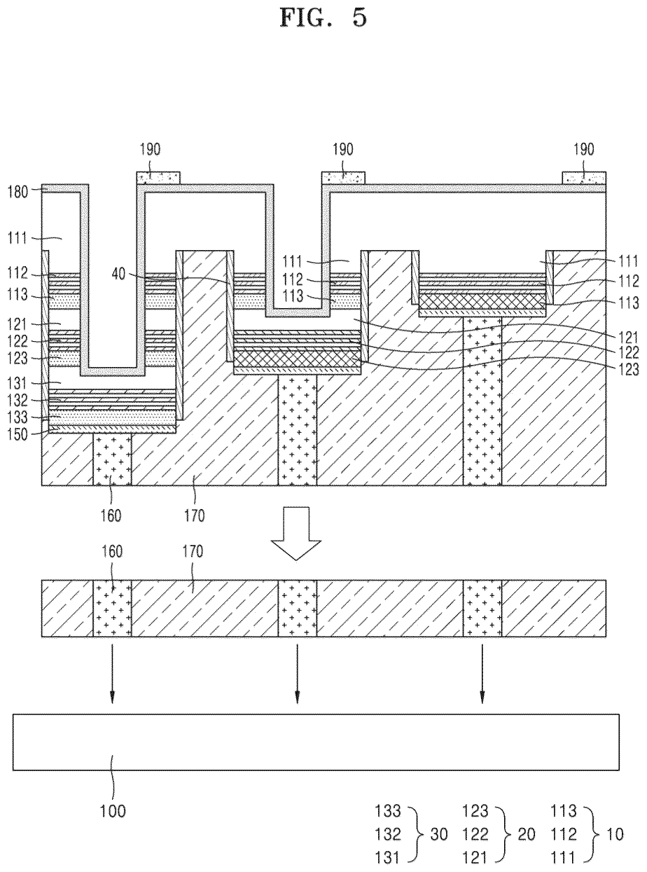

Referring to FIG. 5, after depositing the Mg or Zn film 140 and diffusing Mg or Zn dopants through the heat treatment and the wet cleaning process, a reflective electrode 150 may be formed on the first light-emitting structure 110, the second light-emitting structure 120, and the third light-emitting structure 130. The reflective electrode 150 may include, for example, aluminum (Al). Thereafter, after depositing an insulating material thereon, a first electrode pattern 160 that contacts the reflective electrode 150 within an insulating layer 170 may be formed through, for example, a damascene process (S160). The first electrode pattern 160 may include, for example, copper (Cu).

Thereafter, the first electrode pattern 160 may be flipped over to face a backplane 100, and the first electrode pattern 160 and the backplane 100 may be bonded (S170). For example, the first electrode pattern 160 and the backplane 100 may be bonded, for example, by Cu-Cu hybrid bonding. Additionally, a current diffusion layer 180 may be stacked on the first semiconductor layer 111 of the first light-emitting element 10, and a second electrode pattern 190 may be formed on the current diffusion layer 180. The current diffusion layer 180 may include, for example, indium tin oxide (ITO).

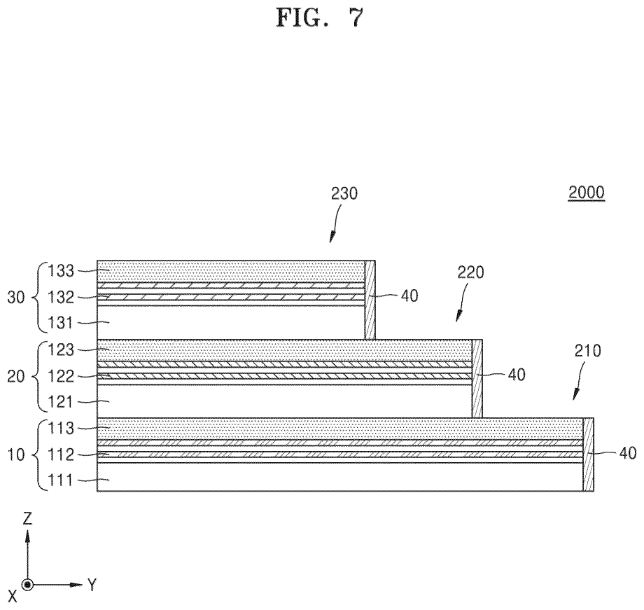

FIG. 7 is a cross-sectional view illustrating a display device according to one or more other embodiments. The differences will be explained mainly with reference to FIG. 1.

Referring to FIG. 7, a display device 2000 may have a cake-like structure in which a first light-emitting structure 210, a second light-emitting structure 220, and a third light-emitting structure 230 are sequentially stacked with step differences, in the third direction (the Z direction). The first light-emitting structure 210 may include the first light-emitting element 10, the second light-emitting structure 220 may include the second light-emitting element 20, and the third light-emitting structure 230 may include the third light-emitting element 30.

According to one or more embodiments, at least one of the second semiconductor layer 113 of the first light-emitting element 10 of the first light-emitting structure 210, the second semiconductor layer 123 of the second light-emitting element 20 of the second light-emitting structure 220, and the second semiconductor layer 133 of the third light-emitting element 30 of the third light-emitting structure 230 may include Mg or Zn dopants.

According to one or more embodiments, when the first semiconductor layers 111, 121, and 131, the active layers 112, 122, and 132, and the second semiconductor layers 113, 123, and 133 include AlGaInP, at least one of the second semiconductor layer 113 of the first light-emitting element 10 of the first light-emitting structure 210, the second semiconductor layer 123 of the second light-emitting element 20 of the second light-emitting structure 220, and the second semiconductor layer 133 of the third light-emitting element 30 of the third light-emitting structure 230 may include the Zn dopants.

According to one or more embodiments, in at least one of the second semiconductor layer 113 of the first light-emitting element 10 of the first light-emitting structure 210, the second semiconductor layer 123 of the second light-emitting element 20 of the second light-emitting structure 220, and the second semiconductor layer 133 of the third light-emitting element 30 of the third light-emitting structure 230, a doping concentration of Mg or Zn on a first surface of the second semiconductor layers 113, 123, and 133 may be greater than a doping concentration of Mg or Zn on a second surface of the second semiconductor layers 113, 123, and 133 opposite to the first surface of the second semiconductor layers 113, 123, and 133.

According to one or more embodiments, a diffusion barrier layer 40 may be provided to extend in the third direction (the Z direction) along wall surfaces where there is a step difference in the first light-emitting structure 210, the second light-emitting structure 220, and the third light-emitting structure 230. As another example, the diffusion barrier layer 40 may be omitted.

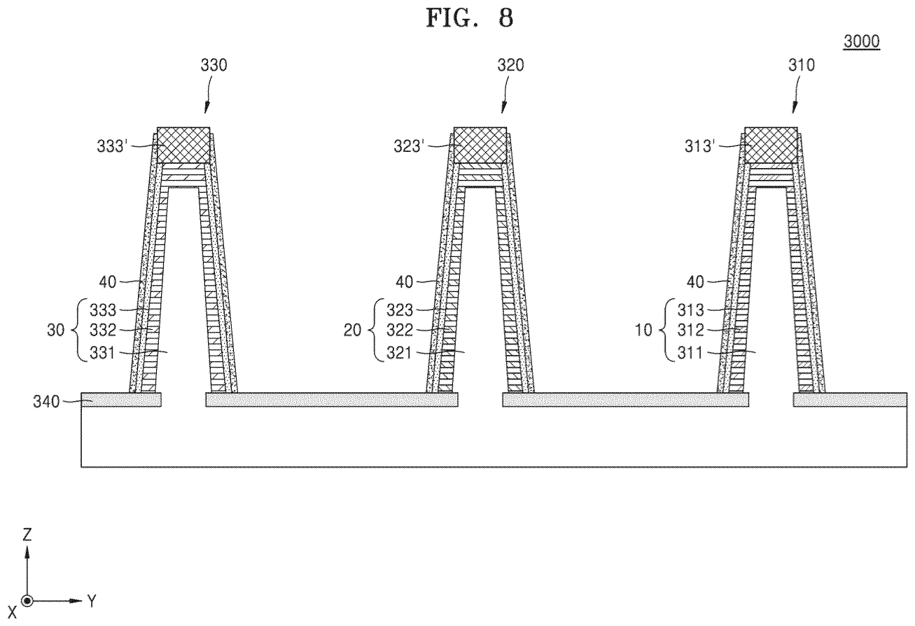

FIG. 8 is a cross-sectional view illustrating a display device according to one or more other embodiments. The differences will be explained mainly with reference to FIG. 1.

Referring to FIG. 8, a display device 3000 may have a horizontal-type structure in which a first light-emitting structure 310, a second light-emitting structure 320, and a third light-emitting structure 330 are arranged side by side and adjacent to each other in the second direction (the Y direction). The first light-emitting structure 310 may include the first light-emitting element 10, the second light-emitting structure 320 may include the second light-emitting element 20, and the third light-emitting structure 330 may include the third light-emitting element 30. The first light-emitting element 10, the second light-emitting element 20, and the third light-emitting element 30 may be selectively grown and formed between growth masks 340. When forming the first light-emitting element 10, the second light-emitting element 20, and the third light-emitting element 30 by selective growth, the concentration of Mg or Zn in the second semiconductor layers 313, 323, and 333 may be non-uniform, and Mg or Zn dopants may be injected into the second semiconductor layers 313, 323, and 333.

According to one or more embodiments, at least one of the second semiconductor layer 313 of the first light-emitting element 10 of the first light-emitting structure 310, the second semiconductor layer 323 of the second light-emitting element 20 of the second light-emitting structure 320, and the second semiconductor layer 333 of the third light-emitting element 30 of the third light-emitting structure 330 may wholly or partially include Mg or Zn dopants.

According to one or more embodiments, at least one of horizontal portions 313′, 323′ and 333′ of the second semiconductor layer 313 of the first light-emitting element 10 of the first light-emitting structure 310, the second semiconductor layer 323 of the second light-emitting element 20 of the second light-emitting structure 320, and the second semiconductor layer 333 of the third light-emitting element 30 of the third light-emitting structure 330 may include Mg or Zn dopants.

According to one or more embodiments, when the first semiconductor layers 311, 321, and 331, the active layers 312, 322, and 332, and the second semiconductor layers 313, 323, and 333 include AlGaInP, at least one of the second semiconductor layer 313 of the first light-emitting element 10 of the first light-emitting structure 310, the second semiconductor layer 323 of the second light-emitting element 20 of the second light-emitting structure 320, and the second semiconductor layer 333 of the third light-emitting element 30 of the third light-emitting structure 330 may include the Zn dopants.

According to one or more embodiments, in at least one of the horizontal portion 313′, 323′ and 333′ of the second semiconductor layer 313 of the first light-emitting element 10 of the first light-emitting structure 310, the second semiconductor layer 323 of the second light-emitting element 20 of the second light-emitting structure 320, and the second semiconductor layer 333 of the third light-emitting element 30 of the third light-emitting structure 330, a doping concentration of Mg or Zn on one surface of the second semiconductor layers 313, 323, and 333 may be greater than a doping concentration of Mg or Zn on the other surface of the second semiconductor layers 313, 323, and 333.

According to one or more embodiments, a diffusion barrier layer 40 may be provided to extend in the third direction (the Z direction) along wall surfaces where there is a step difference in the first light-emitting structure 310, the second light-emitting structure 320, and the third light-emitting structure 330. As another example, the diffusion barrier layer 40 may be omitted, in which case Mg or Zn dopants may be injected into wall surfaces of the second semiconductor layer 313 of the first light-emitting element 10 of the first light-emitting structure 310, the second semiconductor layer 323 of the second light-emitting element 20 of the second light-emitting structure 320, and the second semiconductor layer 333 of the third light-emitting element 30 of the third light-emitting structure 330.

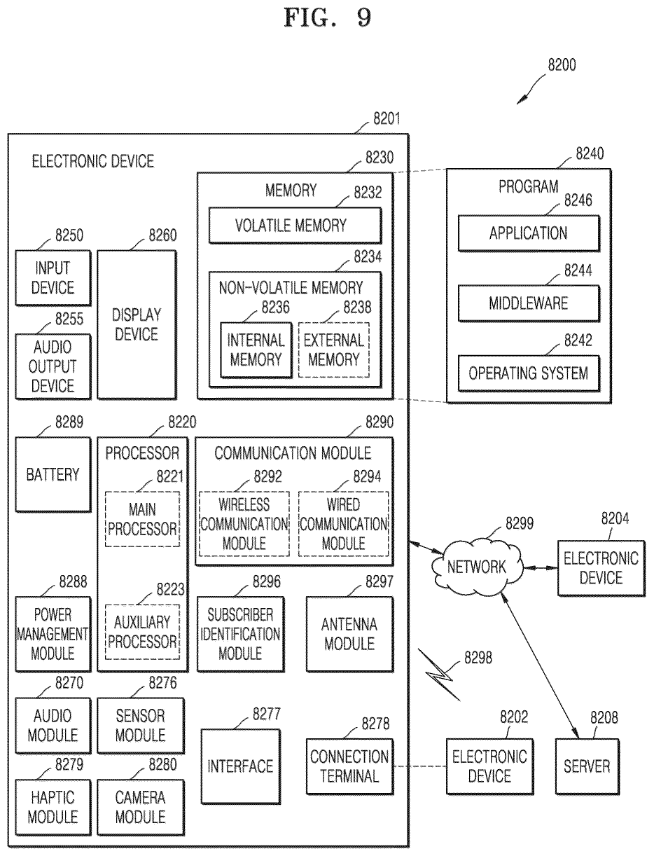

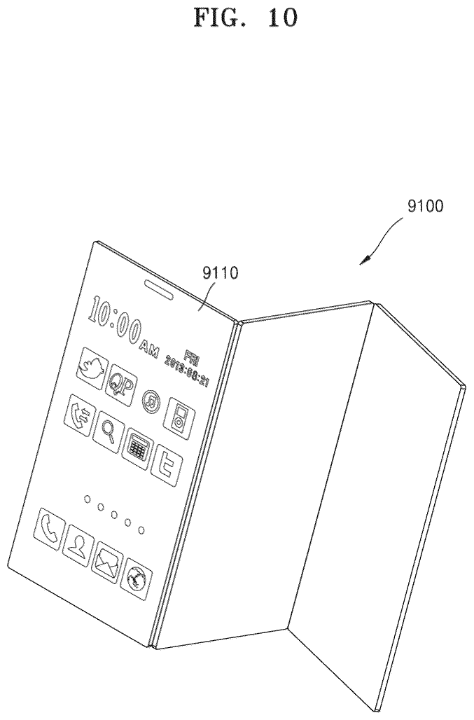

FIG. 9 is a block diagram of an electronic device including a display device according to one or more embodiments.

Referring to FIG. 9, an electronic device 8201 may be provided within a network environment 8200. In the network environment 8200, the electronic device 8201 may communicate with another electronic device 8202 via a first network 8298, such as a short-range wireless communication network, or may communicate with another electronic device 8204 and/or a server 8208 via a second network 8299, such as a long-range wireless communication network. The electronic device 8201 may communicate with the electronic device 8204 via the server 8208. The electronic device 8201 may include a processor 8220, a memory 8230, an input device 8250, an audio output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic device 8201, some of these components may be omitted, or other components may be added. Some of these components may be implemented as a single integrated circuit. For example, the sensor module 8276, such as a fingerprint sensor, an iris sensor, or an illuminance sensor, may be implemented to be embedded in the display device 8260, such as a display.

The processor 8220 may execute software (e.g., a program 8240 to control one or more other components (e.g., hardware, software components, etc.) of the electronic device 8201 connected to the processor 8220, and perform various data processing or calculations. As part of data processing or calculation, the processor 8220 may load commands and/or data received from other components (e.g., the sensor module 8276, the communication module 8290, etc.) into a volatile memory 8232, process the commands and/or data stored in the volatile memory 8232, and store resulting data in a non-volatile memory 8234. The non-volatile memory 8234 may include an internal memory 8236 and an external memory 8238. The processor 8220 may include a main processor 8221 (e.g., a central processing unit, an application processor, etc.) and an auxiliary processor 8223 (e.g., a graphics processing unit, an image signal processor, a sensor hub processor, a communication processor, etc.) that may operate independently or together with the main processor 8221. The auxiliary processor 8223 may use less power than the main processor 8221 and may perform specialized functions.

The auxiliary processor 8223 may control functions and/or states related to some (e.g., the display device 8260, the sensor module 8276, and the communication module 8290, etc.) of the components of the electronic device 8201 on behalf of the main processor 8221 while the main processor 8221 is in an inactive state (for example, a sleep state), or together with the main processor 8221 while the main processor 8221 is in an active state (for example, an application execution state). The auxiliary processor 8223 (e.g., an image signal processor, a communication processor, etc.) may also be implemented as part of other functionally related components (e.g., the camera module 8280, the communication module 8290, etc.).

The memory 8230 may store various data required by components (e.g., the processor 8220, the sensor module 8276, etc.) of the electronic device 8201. The data may include, for example, input data and/or output data for software (e.g., the program 8240, etc.) and instructions associated therewith. The memory 8230 may include the volatile memory 8232 and/or the non-volatile memory 8234.

The program 8240 may be stored as software in the memory 8230 and may include an operating system 8242, middleware 8244, and/or an application 8246.

The input device 8250 may receive commands and/or data to be used in components (e.g., the processor 8220, etc.) of the electronic device 8201, from an external source (e.g., a user) of the electronic device 8201. The input device 8250 may include a remote controller, a microphone, a mouse, a keyboard, and/or a digital pen (e.g., a stylus pen).

The audio output device 8255 may output an audio signal to the outside of the electronic device 8201. The audio output device 8255 may include a speaker and/or a receiver. The speaker may be used for general purposes such as playing multimedia or recordings, and the receiver may be used to receive incoming calls. The receiver may be integrated as part of the speaker or implemented as a separate, independent device.

The display device 8260 may visually provide information to the outside of the electronic device 8201. The display device 8260 may include a display, a holographic device, a projector, and control circuits for controlling these devices. The display device 8260 may include a display device according to one or more embodiments. The display device 8260 may include touch circuitry configured to detect a touch, and/or sensor circuitry (e.g., a pressure sensor, etc.) configured to measure the intensity of a force generated by the touch.

The audio module 8270 may convert sound into an electrical signal, or vice versa. The audio module 8270 may acquire sound through the input device 8250, or output sound through the audio output device 8255 and/or speakers and/or headphones of another electronic device (e.g., the electronic device 8202) directly or wirelessly connected to the electronic device 8201.

The sensor module 8276 may detect operating statuses (e.g., power, temperature, etc.) of the electronic device 8201 or external environmental statuses (e.g., user status, etc.), and generate an electrical signal and/or data value corresponding to the statuses detected. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or a photoresistor sensor.

The interface 8277 may support one or more designated protocols that may be used to allow the electronic device 8201 to connect directly or wirelessly to another electronic device (e.g., the electronic device 8202, etc.). The interface 8277 may include a high definition multimedia Interface (HDMI), a universal serial bus (USB) interface, a secure digital (SD) card interface, and/or an audio interface.

A connection terminal 8278 may include a connector that allows the electronic device 8201 to be physically connected to another electronic device (e.g., the electronic device 8202, etc.). The connection terminal 8278 may include an HDMI connector, a USB connector, an SD card connector, and/or an audio connector (e.g., a headphone connector, etc.).

The haptic module 8279 may convert electrical signals into mechanical stimuli (e.g., vibration, movement, etc.) or electrical stimuli that a user may perceive through tactile or kinesthetic sensations. The haptic module 8279 may include a motor, a piezoelectric element, and/or an electrical stimulation device.

The camera module 8280 may capture still images and videos. The camera module 8280 may include a lens assembly including one or more lenses, image sensors, image signal processors, and/or flashes. The lens assembly included in the camera module 8280 may collect light emitted from a subject that is a target of image capture.

The power management module 8288 may manage power supplied to the electronic device 8201. The power management module 8388 may be implemented as part of a power management integrated circuit (PMIC).

The battery 8289 may supply power to components of the electronic device 8201. The battery 8289 may include a non-rechargeable primary battery, a rechargeable secondary battery, and/or a fuel cell.

The communication module 8290 may support establishment of a direct (i.e., wired) communication channel and/or a wireless communication channel between the electronic device 8201 and another electronic device (e.g., the electronic device 8202, the electronic device 8204, the server 8208, etc.), and performance of communication through the communication channels established. The communication module 8290 may operate independently from the processor 8220 (e.g., an application processor) and may include one or more communication processors that support direct communication and/or wireless communication. The communication module 8290 may include a wireless communication module 8292 (e.g., a cellular communication module, a short-range wireless communication module, a global navigation satellite system (GNSS) communication module, etc.) and/or a wired communication module 8294 (e.g., a local area network (LAN) communication module, a power line communication module, etc.). Any of these communication modules may communicate with other electronic devices via the first network 8298 (e.g., a short-range communication network such as Bluetooth, WiFi Direct, or Infrared Data Association (IrDA)) or the second network 8299 (e.g., a long-range communication network such as a cellular network, the Internet, or a computer network (LAN, wide area network (WAN), etc.)). These different types of communication modules may be integrated into a single component (e.g., a single chip) or implemented as multiple separate components (e.g., multiple chips). The wireless communication module 8292 may identify and authenticate the electronic device 8201 within a communication network, such as the first network 8298 and/or the second network 8299, using subscriber information (e.g., international mobile subscriber identity (IMSI), etc.) stored in the subscriber identification module 8296.

The antenna module 8297 may transmit signals and/or power to, or receive signals and/or power from the outside (e.g., another electronic device). The antenna may include a radiator formed of a conductive pattern on a substrate (e.g., a printed circuit board (PCB), etc.). The antenna module 8297 may include one or more antennas. When a plurality of antennas are included, any antenna suitable for a communication method used in the communication network, such as the first network 8298 or the second network 8299, may be selected from among the plurality of antennas by the communication module 8290. Signals and/or power may be transmitted or received between the communication module 8290 and other electronic devices via the selected antenna. In addition to the antenna, other components (e.g., a radio-frequency integrated circuit (RFIC), etc.) may be included as part of the antenna module 8297.

Some of the components may be connected to each other and exchange signals (e.g., commands, data, etc.) through communication methods between peripheral devices (e.g., bus, general purpose input and output (GPIO), serial peripheral interface (SPI), mobile industry processor interface (MIPI), etc.).

Commands or data may be transmitted or received between the electronic device 8201 and the external electronic device 8204 via the server 8208 connected to the second network 8299. The other electronic devices 8202 and 8204 may be the same or a different type of device as the electronic device 8201. All or part of operations executed on the electronic device 8201 may be executed on one or more of the other electronic devices 8202, 8204, and 8208. For example, when the electronic device 8201 needs to perform a certain function or service, instead of executing the function or service itself, the electronic device 8201 may request one or more other electronic devices to perform part or all of the function or service. The one or more other electronic devices that receive the request may execute additional functions or services related to the request and may transmit the results of the execution to the electronic device 8201. For this purpose, cloud computing, distributed computing, and/or client-server computing technologies may be utilized.

FIG. 10 illustrates an example of an electronic device applied to a mobile device, according to one or more embodiments.

Referring to FIG. 10, a mobile device 9100 may include a display device 9110, and the display device 9110 may include display devices according to one or more embodiments. The display device 9110 may have a foldable structure, for example, a multi-foldable structure.

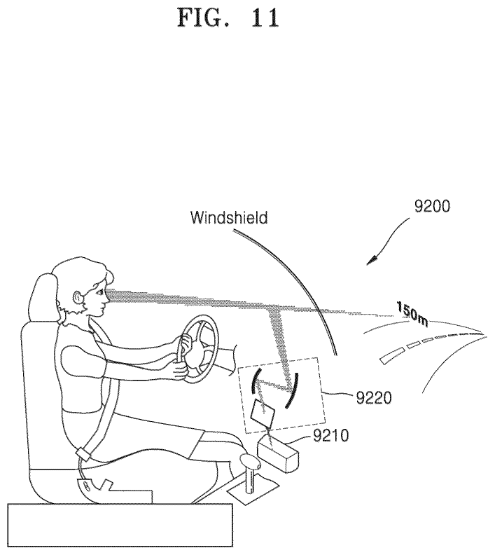

FIG. 11 illustrates an example of a display device applied to a car, according to one or more embodiments. The display device may include a head-up display device 9200 for an automobile, and may include a display 9210 provided in an area of the automobile, and an optical path changing member 9220 that changes an optical path so that the driver may view an image generated by the display 9210.

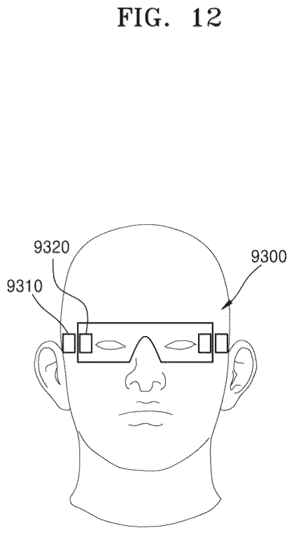

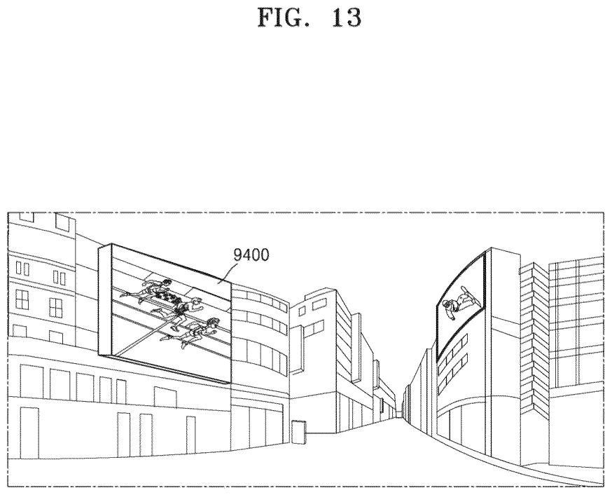

FIG. 12 illustrates an example of a display device applied to an augmented reality glass or a virtual reality glass, according to one or more embodiments.

Referring to FIG. 12, an augmented reality glass 9300 may include a projection system 9310 that forms an image and an element 9320 that guides the image from the projection system 9310 into the user's eyes. The projection system 9310 may include a display device according to one or more embodiments.

FIG. 13 illustrates an example in which a display device according to one or more embodiments is applied to a large signage. A signage 9400 may be used for outdoor advertising using digital information display, and may control advertising content, etc. through a communication network. The signage 9400 may be implemented, for example, through the electronic devices as described with reference to FIG. 9.

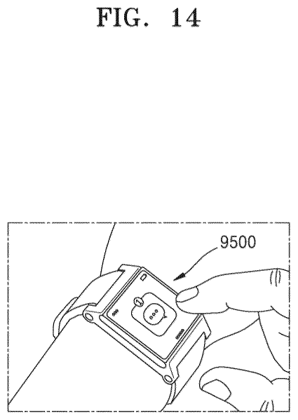

FIG. 14 illustrates an example in which a display device according to one or more embodiments is applied to a wearable display. A wearable display 9500 may include a display device according to one or more embodiments and may be implemented through the electronic devices as described with reference to FIG. 9.

The display device according to one or more embodiments may also be applied to various products such as a rollable TV, a stretchable display, etc.

The embodiments described above are summarized as follows.

A display device according to one or more embodiments may include a first light-emitting structure including a first light-emitting element, a second light-emitting structure including a second light-emitting element, and a third light-emitting structure including a third light-emitting element. Each of the first light-emitting element, the second light-emitting element, and the third light-emitting element may include a structure in which a first semiconductor layer of a first conductivity type, an active layer, and a second semiconductor layer of a second conductivity type are sequentially stacked, and at least one of the second semiconductor layer of the second conductivity type in the first light-emitting element, the second semiconductor layer of the second conductivity type in the second light-emitting element, the second semiconductor layer of the second conductivity type in the third light-emitting element includes a Mg or Zn dopant.

In the display device, the first semiconductor layer of the first conductivity type, the active layer, and the second semiconductor layer of the second conductivity type of each of the first light-emitting element, the second light-emitting element, and the third light-emitting element may include GaN or InGaN, and at least one of the second semiconductor layer of the second conductivity type in the first light-emitting element, the second semiconductor layer of the second conductivity type in the second light-emitting element, the second semiconductor layer of the second conductivity type in the third light-emitting element may include a Mg dopant.

In the display device, the first semiconductor layer of the first conductivity type, the active layer, and the second semiconductor layer of the second conductivity type of each of the first light-emitting element, the second light-emitting element, and the third light-emitting element may include AlGaInP, and at least one of the second semiconductor layer of the second conductivity type in the first light-emitting element, the second semiconductor layer of the second conductivity type in the second light-emitting element, the second semiconductor layer of the second conductivity type in the third light-emitting element may include the Zn dopant.

In the display device, a doping concentration of Mg or Zn on one surface of at least one of the second semiconductor layer of the second conductivity type of the first light-emitting element, the second semiconductor layer of the second conductivity type of the second light-emitting element, and the second semiconductor layer of the second conductivity type of the third light-emitting element may be greater than a doping concentration of Mg or Zn on the other surface thereof.

In the display device, at least one of the second semiconductor layer of the second conductivity type of the first light-emitting element, the second semiconductor layer of the second conductivity type of the second light-emitting element, and the second semiconductor layer of the second conductivity type of the third light-emitting element may have a doping concentration of Mg or Zn that decreases from one surface thereof to the other surface thereof.

In the display device, in at least one of the second semiconductor layer of the second conductivity type of the first light-emitting element, the second semiconductor layer of the second conductivity type of the second light-emitting element, and the second semiconductor layer of the second conductivity type of the third light-emitting element, a doping concentration of Mg or Zn on one surface of the second semiconductor layer of the second conductivity type may be greater than or equal to about 5×10²⁰cm⁻³ but less than or equal to about 2×10²¹cm⁻³.

In the display device, in at least one of the second semiconductor layer of the second conductivity type of the first light-emitting element, the second semiconductor layer of the second conductivity type of the second light-emitting element, and the second semiconductor layer of the second conductivity type of the third light-emitting element, a doping concentration of Mg or Zn on one surface of the second semiconductor layer of the second conductivity type may be greater than or equal to about 7×10²⁰cm⁻³ but less than or equal to about 2×10²¹cm⁻³.

In the display device, in at least one of the second semiconductor layer of the second conductivity type of the first light-emitting element, the second semiconductor layer of the second conductivity type of the second light-emitting element, and the second semiconductor layer of the second conductivity type of the third light-emitting element, a doping concentration of Mg or Zn on one surface of the second semiconductor layer of the second conductivity type may be greater than or equal to about 8×10²⁰cm⁻³ but less than or equal to about 2×10²¹cm⁻³.

In the display device, at least one of the first light-emitting element, the second light-emitting element, and the third light-emitting element may include a diffusion barrier layer.

In the display device, at least one of the first light-emitting element, the second light-emitting element, and the third light-emitting element may include a diffusion barrier layer, and the diffusion barrier layer may include at least one of AlN, TiN, SiN, Al₂O₃ or a combination thereof.

In the display device, the second light-emitting structure may include the first light-emitting element and the second light-emitting element stacked on the first light-emitting element, and the third light-emitting structure may include the first light-emitting element, the second light-emitting element stacked on the first light-emitting element, and the third light-emitting element stacked on the second light-emitting element.

In the display device, the second light-emitting structure may include the first light-emitting element and the second light-emitting element stacked on the first light-emitting element, and the third light-emitting structure may include the first light-emitting element, the second light-emitting element stacked on the first light-emitting element, and the third light-emitting element stacked on the second light-emitting element, and the second semiconductor layer of the second conductivity type of the first light-emitting element includes a Mg or Zn dopant, and the second semiconductor layer of the second conductivity type of the second light-emitting element may include a Mg or Zn dopant.

In the display device, the first light-emitting structure, the second light-emitting structure, and the third light-emitting structure may be sequentially stacked.

In the display device, the first light-emitting structure, the second light-emitting structure, and the third light-emitting structure may be arranged horizontally side by side and adjacent to each other.

In the display device, the first light-emitting structure, the second light-emitting structure, and the third light-emitting structure may be arranged horizontally side by side, and a horizontal portion of at least one of the second semiconductor layer of the second conductivity type of the first light-emitting structure, the second semiconductor layer of the second conductivity type of the second light-emitting structure, and the second semiconductor layer of the second conductivity type of the third light-emitting structure may include a Mg or Zn dopant.

A method of manufacturing a display device according to one or more embodiments may include forming a first light-emitting element, a second light-emitting element, and a third light-emitting element each having a structure in which a first semiconductor layer of a first conductivity type, an active layer, and a second semiconductor layer of a second conductivity type are sequentially stacked, depositing a Mg or Zn film on at least one of the second semiconductor layer of the second conductivity type in the first light-emitting element, the second semiconductor layer of the second conductivity type in the second light-emitting element, and the second semiconductor layer of the second conductivity type in the third light-emitting element, diffusing a Mg or Zn dopant by heat treating at least one of the first light-emitting element, the second light-emitting element, and the third light-emitting element, and removing residual Mg or Zn from at least one of the first light-emitting element, the second light-emitting element, and the third light-emitting element.

In the method, the first semiconductor layer of the first conductivity type, the active layer, and the second semiconductor layer of the second conductivity type of each of the first light-emitting element, the second light-emitting element, and the third light-emitting element may include GaN or InGaN, and at least one of the second semiconductor layer of the second conductivity type in the first light-emitting element, the second semiconductor layer of the second conductivity type in the second light-emitting element, the second semiconductor layer of the second conductivity type in the third light-emitting element may include a Mg dopant.

In the method, the first semiconductor layer of the first conductivity type, the active layer, and the second semiconductor layer of the second conductivity type of each of the first light-emitting element, the second light-emitting element, and the third light-emitting element may include AlGaInP, and at least one of the second semiconductor layer of the second conductivity type in the first light-emitting element, the second semiconductor layer of the second conductivity type in the second light-emitting element, the second semiconductor layer of the second conductivity type in the third light-emitting element may include the Zn dopant.

In the method, a doping concentration of Mg or Zn on one surface of at least one of the second semiconductor layer of the second conductivity type of the first light-emitting element, the second semiconductor layer of the second conductivity type of the second light-emitting element, and the second semiconductor layer of the second conductivity type of the third light-emitting element may be greater than a doping concentration of Mg or Zn on the other surface thereof.

In the method, the method may further include, prior to depositing the Mg or Zn film on at least one of the second semiconductor layer of the second conductivity type in the first light-emitting element, the second semiconductor layer of the second conductivity type in the second light-emitting element, and the second semiconductor layer of the second conductivity type in the third light-emitting element, forming a diffusion barrier layer on at least one of the first light-emitting element, the second light-emitting element, and the third light-emitting element.

According to one or more embodiments, a display device with improved light extraction efficiency and brightness, and a method of manufacturing the display device may be provided. The embodiments described above are merely examples, and those skilled in the art will appreciate that various modifications and equivalent other embodiments may be made from the above-described examples. Therefore, the true scope of technical protection according to the embodiments should be defined by the technical idea described in the following patent claims.

It should be understood that embodiments described herein should be considered in a descriptive sense only and not for purposes of limitation. Descriptions of features or aspects within each embodiment should typically be considered as available for other similar features or aspects in other embodiments.

While embodiments have been described with reference to the figures, it will be understood by those of ordinary skill in the art that various changes in form and details may be made therein without departing from the spirit and scope as defined by the following claims and their equivalents.

What is claimed is:

1. A display device comprising:
a first light-emitting structure comprising a first light-emitting element;
a second light-emitting structure comprising a second light-emitting element; and
a third light-emitting structure comprising a third light-emitting element,
wherein the first light-emitting element, the second light-emitting element, and the third light-emitting element respectively comprises a first semiconductor layer of a first conductivity type, an active layer, and a second semiconductor layer of a second conductivity type that are sequentially stacked, and
at least one of the second semiconductor layer in the first light-emitting element, the second semiconductor layer in the second light-emitting element, and the second semiconductor layer in the third light-emitting element comprises a magnesium (Mg) dopant or zinc (Zn) dopant.

2. The display device of claim 1, wherein the first semiconductor layer, the active layer, and the second semiconductor layer in each of the first light-emitting element, the second light-emitting element, and the third light-emitting element comprise gallium nitride (GaN) or indium gallium nitride (InGaN), and
wherein at least one of the second semiconductor layer in the first light-emitting element, the second semiconductor layer in the second light-emitting element, and the second semiconductor layer in the third light-emitting element comprises a Mg dopant.

3. The display device of claim 1, wherein the first semiconductor layer, the active layer, and the second semiconductor layer in each of the first light-emitting element, the second light-emitting element, and the third light-emitting element comprise aluminum gallium indium phosphide (AlGaInP), and
wherein at least one of the second semiconductor layer in the first light-emitting element, the second semiconductor layer in the second light-emitting element, and the second semiconductor layer in the third light-emitting element comprises a Zn dopant.

4. The display device of claim 1, wherein a doping concentration of Mg or a doping concentration of Zn on a first surface of at least one of the second semiconductor layer in the first light-emitting element, the second semiconductor layer in the second light-emitting element, and the second semiconductor layer in the third light-emitting element is greater than a doping concentration of Mg or a doping concentration of Zn on a second surface of surface thereof opposite to the first surface.

5. The display device of claim 1, wherein a doping concentration of Mg or a doping concentration of Zn of at least one of the second semiconductor layer in the first light-emitting element, the second semiconductor layer in the second light-emitting element, and the second semiconductor layer in the third light-emitting element decreases from a first surface of at least one of the second semiconductor layer in the first light-emitting element, the second semiconductor layer in the second light-emitting element, and the second semiconductor layer in the third light-emitting element to a second surface thereof opposite to the first surface.

6. The display device of claim 1, wherein, in at least one of the second semiconductor layer in the first light-emitting element, the second semiconductor layer in the second light-emitting element, and the second semiconductor layer in the third light-emitting element, a doping concentration of Mg or Zn on a first surface of the second semiconductor layer is greater than or equal to 5×10²⁰cm⁻³ and less than or equal to 2×10²¹cm⁻³.

7. The display device of claim 1, wherein, in at least one of the second semiconductor layer in the first light-emitting element, the second semiconductor layer in the second light-emitting element, and the second semiconductor layer in the third light-emitting element, a doping concentration of Mg or Zn on a first surface of the second semiconductor layer is greater than or equal to 7×10²⁰cm⁻³ and less than or equal to 2×10²¹cm⁻³.

8. The display device of claim 1, wherein, in at least one of the second semiconductor layer in the first light-emitting element, the second semiconductor layer in the second light-emitting element, and the second semiconductor layer in the third light-emitting element, a doping concentration of Mg or Zn on a first surface of the second semiconductor layer is greater than or equal to 8×10²⁰cm⁻³ and less than or equal to 2×10²¹cm⁻³.

9. The display device of claim 1, wherein at least one of the first light-emitting element, the second light-emitting element, and the third light-emitting element comprises a diffusion barrier layer.

10. The display device of claim 1, wherein at least one of the first light-emitting element, the second light-emitting element, and the third light-emitting element comprises a diffusion barrier layer, and
wherein the diffusion barrier layer comprises at least one of aluminum nitride (AlN), titanium nitride (TiN), silicon nitride (SiN), aluminum oxide (Al₂O₃) or a combination thereof.

11. The display device of claim 1, wherein the second light-emitting structure comprises the first light-emitting element and the second light-emitting element stacked on the first light-emitting element, and
wherein the third light-emitting structure comprises the first light-emitting element, the second light-emitting element stacked on the first light-emitting element, and the third light-emitting element stacked on the second light-emitting element.

12. The display device of claim 1, wherein the second light-emitting structure comprises the first light-emitting element and the second light-emitting element stacked on the first light-emitting element,
wherein the third light-emitting structure comprises the first light-emitting element, the second light-emitting element stacked on the first light-emitting element, and the third light-emitting element stacked on the second light-emitting element, and
wherein the second semiconductor layer in the first light-emitting element comprises a Mg dopant or a Zn dopant, and the second semiconductor layer in the second light-emitting element comprises a Mg dopant or a Zn dopant.

13. The display device of claim 1, wherein the first light-emitting structure, the second light-emitting structure, and the third light-emitting structure are sequentially stacked in a vertical direction.

14. The display device of claim 1, wherein the first light-emitting structure, the second light-emitting structure, and the third light-emitting structure are adjacent to each other in a horizontal direction.

15. The display device of claim 1, wherein the first light-emitting structure, the second light-emitting structure, and the third light-emitting structure are adjacent to each other in a horizontal direction, and
wherein a portion of at least one of the second semiconductor layer in the first light-emitting structure, the second semiconductor layer in the second light-emitting structure, and the second semiconductor layer in the third light-emitting structure comprises a Mg dopant or a Zn dopant.

16. A method of manufacturing a display device, the method comprising:
forming a first light-emitting element, a second light-emitting element, and a third light-emitting element respectively comprising a first semiconductor layer of a first conductivity type, an active layer, and a second semiconductor layer of a second conductivity type that are sequentially stacked;
depositing a magnesium (Mg) film or a zinc (Zn) film on at least one of the second semiconductor layer in the first light-emitting element, the second semiconductor layer in the second light-emitting element, and the second semiconductor layer in the third light-emitting element;
diffusing a Mg dopant or a Zn dopant by heat treating at least one of the first light-emitting element, the second light-emitting element, and the third light-emitting element; and
removing residual Mg or Zn from at least one of the first light-emitting element, the second light-emitting element, and the third light-emitting element.

17. The method of claim 16, wherein the first semiconductor layer, the active layer, and the second semiconductor layer in the first light-emitting element, the second light-emitting element, and the third light-emitting element, respectively, comprise gallium nitride (GaN) or indium gallium nitride (InGaN), and
wherein at least one of the second semiconductor layer in the first light-emitting element, the second semiconductor layer in the second light-emitting element, and the second semiconductor layer in the third light-emitting element comprises a Mg dopant.

18. The method of claim 16, wherein the first semiconductor layer, the active layer, and the second semiconductor layer in the first light-emitting element, the second light-emitting element, and the third light-emitting element, respectively comprise aluminum gallium indium phosphide (AlGaInP), and
wherein at least one of the second semiconductor layer in the first light-emitting element, the second semiconductor layer in the second light-emitting element, and the second semiconductor layer in the third light-emitting element comprises a Zn dopant.

19. The method of claim 16, wherein a doping concentration of Mg or a doping concentration of Zn on a first surface of at least one of the second semiconductor layer in the first light-emitting element, the second semiconductor layer in the second light-emitting element, and the second semiconductor layer in the third light-emitting element is greater than a doping concentration of Mg or a doping concentration of Zn on a second surface opposite to the first surface.

20. The method of claim 16, further comprising,
prior to the depositing of the Mg film or the Zn film on at least one of the second semiconductor layer in the first light-emitting element, the second semiconductor layer in the second light-emitting element, and the second semiconductor layer in the third light-emitting element,
forming a diffusion barrier layer on at least one of the first light-emitting element, the second light-emitting element, and the third light-emitting element.
